(19) United States
(12) Patent Application Publication
(10) Pub. No.: US 2009/0061608 A1
(43) Pub. Date: Mar. 5, 2009

(54) METHOD OF FORMING A SEMICONDUCTOR DEVICE HAVING A SILICON DIOXIDE LAYER

(76) Inventors: Tushar P. Merchant, Austin, TX (US); Lakshmanna Vishnubhotla, Hopewell Junction, NY (US); Ramachandran Muralidhar, Austin, TX (US); Rajesh A. Rao, Austin, TX (US); Sriram Kalpat, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/846,633

(22) Filed: Aug. 29, 2007

(51) Int. Cl. H01L 21/28

(52) U.S. Cl. 438/591; 438/787; 438/763; 257/E21.18

(57) ABSTRACT

A method of depositing a silicon dioxide layer for a semiconductor device. The method includes depositing the silicon dioxide layer to have a silicon concentration of greater than 30 atomic percent and a nitrogen concentration of less than 5 atomic percent. The depositing includes flowing nitric oxide gas with a silicon precursor over a substrate. In one example, the silicon precursor and nitric oxide are flowed over a substrate with the substrate being at a temperature in a range of approximately 600 to approximately 900 degrees Celsius. In one example, the silicon dioxide layer is formed on a layer including charge storage memory material.

### BACKGROUND

1. Field

This disclosure relates generally to semiconductor devices, and more specifically, to semiconductor devices having a silicon dioxide layer.

2. Related Art

As semiconductor scaling continues, integration problems are encountered which can affect the performance and reliability of semiconductor devices. For non-volatile memory (NVM) devices, such as electrically erasable programmable random access memories (E²PROMs) these integration problems can include leakage or loss of the charge stored in the memory cell's floating gate from thinning of the device's tunnel oxide. Nanocrystal technology is an area currently under investigation as a replacement for conventional floating gates in scaled NVM devices. One specific application uses singularly isolated silicon nanocrystals as discrete charge storage elements to store the charge in the floating gate. The isolated nature of each of the nanocrystals reduces the floating gate's vulnerability to charge leakage that results from defects in the underlying tunnel oxide. Instead of providing a leakage path for the entire floating gate, the defect(s) provide a leakage path only for individually charged nanocrystals. Typically, the charge leakage from a single nanocrystal will not affect the overall charge associated with the floating gate.

A current problem with the nanocrystal NVM devices is charge trapping in the control dielectric, which overlies the nanocrystals. The charge trapping undesirably increases the threshold voltage of the device during device operation. Therefore, a need exists to decrease charge trapping in nanocrystal NVM devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-section of a portion of a semiconductor device in accordance with an embodiment;

FIG. 2 illustrates the semiconductor device of FIG. 1 after further processing in accordance with an embodiment; and

FIG. 3 illustrates a graph showing the concentration of nitrogen over a given depth for various precursors.

### DETAILED DESCRIPTION

Charge trapping in the nanocrystal NVM device undesirably increases the threshold voltage of the device during device operation. This charge trapping is due to structural and chemical defects and weak bonds in the control dielectric. For example, the Si—H, Si—OH, and Si═Si bonds that may form in a control dielectric deposited by chemical vapor deposition (CVD) are weak bonds. These weak bonds can be broken during charging and discharging operations of the device by high-energy carriers injected into or from the discrete charge storage elements. Trap states result from broken weak bonds. Additionally, there may be structural or chemical defects and dangling bonds created in the control dielectric during the deposition process itself. These dangling bonds will attract charge and become charged traps. To minimize defects and weak bonds, in one embodiment, the control dielectric is deposited using nitric oxide (NO) as a precursor.

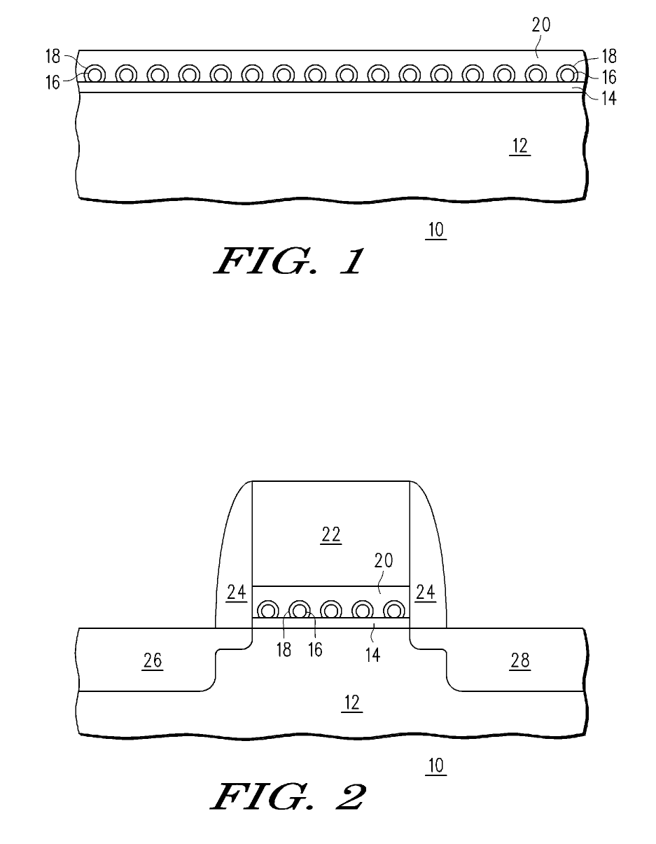

FIG. 1 illustrates a cross-section of a portion of a semiconductor device 10. In one embodiment, the semiconductor device 10 includes a semiconductor substrate 12, a tunnel dielectric 14, nanocrystals 16, passivation 18, and a control dielectric 20. The semiconductor substrate 12 may include any semiconductor material or combinations of materials, such as gallium arsenide, silicon germanium, silicon-on-insulator (SOI), silicon on sapphire, silicon, monocrystalline silicon, the like, and combinations of the above. Although not shown, the semiconductor substrate 12 may includes isolation regions to isolate electrically the active regions of the semiconductor substrate 12 from each other. Any method, such as shallow trench isolation (STI), local oxidation of silicon (LOCOS), buffered poly LOCOS, or the like, can be used to form the isolation regions.

Over the substrate 12 a tunnel dielectric or (first) dielectric (layer) 14 is formed. The tunnel dielectric 14 may include silicon dioxide, aluminum oxide, nitrided silicon dioxide, silicon nitride, hafnium oxide (HfO₂), zirconium oxide (ZrO₂), tantalum pentoxide (Ta₂O₅), or the like, or combinations of the above. In accordance with one embodiment, a silicon dioxide tunnel dielectric is formed using a conventional thermal oxidation process. Alternative deposition methods can be used depending on the dielectric material being deposited. The deposition methods may include chemical vapor deposition (CVD), atomic layer deposition (ALD), physical vapor deposition (PVD), or the like. In one specific embodiment, the thickness of the silicon dioxide tunnel dielectric layer is approximately 6 nanometers (nm). In one embodiment, the tunnel dielectric has a silicon dioxide or an electrical equivalent oxide thickness (EOT) in a range of approximately 4 to approximately 9 nm. For the purposes of this specification, the electrical equivalent oxide thickness refers to the thickness of a dielectric scaled by the ratio of its dielectric constant to the dielectric constant of silicon dioxide (silicon dioxide having a dielectric constant of approximately 3.9).

In one embodiment, a nitride layer (not shown) is formed over the tunnel dielectric 14 by for example, CVD, PVD, the like, or combinations thereof. In one embodiment, the nitride layer is silicon nitride and has a thickness less than approximately 1 nm. In one embodiment, a charge storage memory material, such as discrete charge storage elements or discontinuous charge storage elements 16 (e.g., nanoclusters or nanocrystals) are formed on the nitride layer, if present.

If the nitride layer is not formed, as shown in the embodiment illustrated in FIG. 1, a charge storage memory material, such as discrete charge storage elements 16, are formed over and in contact with (i.e., on) the tunnel dielectric 14. The discrete charge storage elements 16 may include silicon, however another suitable charge storage material can be used. In addition, the discrete charge storage elements 16 may be doped. In one embodiment, the discrete charge storage elements 16 may be deposited through a controlled low pressure chemical vapor deposition (LPCVD), rapid thermal chemical vapor deposition (RTCVD) or ultra-high vacuum chemical vapor deposition (UHVCVD) process. In one embodiment, the discrete charge storage elements 16 have a diameter between approximately 4 nm and approximately 10 nm. (For purposes of this specification, the nanocluster diameter is defined as the largest width of the nanocluster.) Although the discrete charge storage elements 16 are illustrated as spheres in FIG. 1, they may be approximately hemispherical in shape due to the deposition process. The discrete charge storage elements 16 may be present in a density of at least 10¹¹ nanoclusters per square centimeter.

In the embodiment, illustrated in FIG. 1, passivation 18 is formed over the discrete charge storage elements 16. In other embodiments, the passivation 18 may not be present. The passivation 18, in one embodiment, is a thermally grown oxide. The oxide may be grown using nitric oxide (NO), nitrous oxide (N₂O), the like, or combinations of the above.

A control dielectric or (second) dielectric (layer) 20 is formed over the discrete charge storage elements 16 and the passivation 18, if present. In one embodiment, the control dielectric layer is approximately 5 to approximately 20 nanometers thick. In one embodiment, the control dielectric 20 includes silicon. In one embodiment, the control dielectric 20 is primarily silicon dioxide; in other words, the control dielectric 20 consists essentially of silicon dioxide, even though some nitrogen or other element, such as fluorine may be present. The control dielectric 20 is formed by CVD, or more preferably by LPCVD. In one embodiment, the temperature at which the semiconductor substrate 12 is heated to is between approximately 600 to approximately 900 degrees Celsius. (Hence, in this embodiment all the layers on the semiconductor substrate 12 are at temperature in this range.) The lower temperature is chosen so that the reaction proceeds fast enough for manufacturability but allows for a silicon-including precursor to decompose so that a high quality film is formed. The higher temperature is chosen so that the control dielectric 20 does not form so quickly (e.g., less than 1 second) that the process is not manufacturable.

The precursors used in the CVD process include a silicon-including precursor and a nitrogen and oxygen-including precursor. The silicon-including precursor can also be referred to as a silicon precursor because at least the silicon is being incorporated into the layer being formed. The nitrogen and oxygen-including precursor can be referred to as an oxygen precursor or a nitrogen precursor because both the nitrogen and the oxygen are being incorporated in to the layer being formed. The silicon-including precursor may be silane (SiH₄), silicon tetrafluoride (SiF₄), difluorosilane (SiH₂F₂), fluorosilane (SiH₃F), dichlorosilane, deuterated silane (SiD₄), the like, or combinations of the above. Silicon tetrafluoride may be desirable over silane because any fluorine that may be incorporate into the film will contribute to strong bonds, such as Si—F bonds, and hence, less dangling bonds are expected to be created. If a fluorine containing silicon precursor such as SiF₄, SiH₂F₂, or SiH₃F is used, it may be desirable to limit the amount of this precursor as too much fluorine in the control dielectric 20 can undesirably lower the material's dielectric constant. A lower dielectric constant undesirably increases the operating voltage of the semiconductor device.

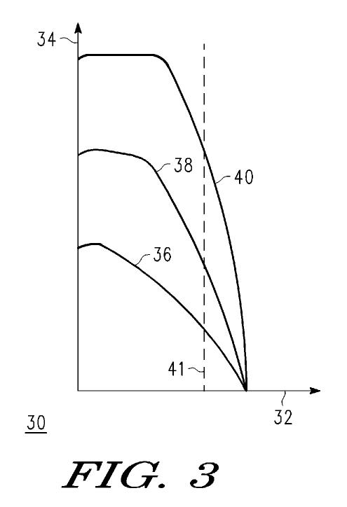

The nitrogen and oxygen-including precursor is preferably nitric oxide (NO). Nitric oxide is more reactive than nitrous oxide and rapidly incorporates both oxygen and nitrogen in the film. Nitrous oxide on the other hand has to first decompose into nitric oxide before it can decompose into nitrogen and oxygen that can grow the deposited film. Therefore, better thickness uniformity is achieved using NO, along with an improved stoichiometry and fewer dangling bonds, and an increased concentration of nitrogen can be incorporated in the control dielectric 20. FIG. 3 illustrates this advantage of NO over N₂O.

FIG. 3 is a simplified version of experimental data showing the uniformity of the nitrogen in a dielectric under different processing conditions. The variable in the processes used to generate lines 36, 38, and 40 is the nitrogen and oxygen-including precursor. The temperature and pressure was the same for all processes. For example, the temperature was approximately 700 degrees Celsius and the pressure was approximately 50 Torr. In FIG. 3, the x-axis 32 is the depth (for example, in nanometers) in the dielectric. The y-axis 34 is the nitrogen concentration (for example, in atoms percentimeter cubed). The intersection of the x-axis 32 and y-axis 34 is the top of the dielectric layer. Dotted line 41 illustrates the interface between the dielectric layer and an underlying silicon substrate. The line 36 illustrates the concentration of nitrogen over a depth when the dielectric is formed using LPCVD with silane and N₂O. The line 38 illustrates the concentration of nitrogen over a depth when the dielectric is formed using LPCVD with silane and both NO and N₂O. The line 40 illustrates the concentration of nitrogen over a depth when the dielectric is formed using LPCVD with silane and NO. FIG. 3 shows that using NO as the precursor results in a higher concentration of nitrogen with more uniform distribution through the thickness of the dielectric as compared to using N₂O alone or in combination with NO. Because nitrogen passivates dangling bonds, the increased concentration of nitrogen eliminates more dangling bonds during the deposition process. Furthermore, the use of an NO precursor enables the possibility to widely vary the incorporated nitrogen content in the film (which is uniform across the thickness) which is not possible with the N₂O precursor alone.

By depositing the control dielectric 20, dangling bonds are created everywhere within the bulk of the control dielectric 20. In contrast, in a thermally grown dielectric, dangling bonds are formed predominantly at the interface of the substrate (e.g., a silicon layer) and the thermally grown dielectric (e.g., silicon dioxide) due to lattice mismatch. By using NO as a precursor when depositing the control dielectric 20, the dangling bonds that are present throughout the control dielectric 20 are passivated due to the improved reactivity leading to more complete oxidation. Reducing the dangling bonds minimizes an increase in threshold voltage of the device, which occurs due to charge trapping at the dangling bonds. This method is also better than a post deposition anneal with NO since it minimizes dangling bond formation rather than relying on subsequent diffusion to passivate existing dangling bonds. An additional benefit with depositing the control dielectric with an NO precursor is the precursor's capability to passivate nanoclusters and the tunnel oxide to prevent further oxidation in case a passivation layer 18 has not been used.

In one embodiment, N₂O is flowed with the NO precursor and silicon-including precursor. In this embodiment, the NO and N₂O can be pulsed to obtain a desired nitrogen concentration and profile in the control dielectric 20.

In one embodiment, the ratio of silicon-including precursor to the nitrogen and oxygen including precursor is at least 1 to 5. In other words, at least 5 times as much by volume of the nitrogen and oxygen-including precursor gas as the silicon-including precursor is flown.

If the above deposition processes for the control dielectric 20 are used, a silicon dioxide layer having a silicon concentration of greater than approximately 30 atomic percent and a nitrogen concentration less than 5 atomic percent may be formed. In one embodiment, the nitrogen concentration is greater than 1 atomic percent. Hence, the nitrogen concentration may be between 1 and 5 atomic percent. Having the nitrogen concentration greater than 1 atomic percent allows for enough nitrogen to be present to passivate the dangling bonds. Maintaining a nitrogen concentration less than 5 atomic percent is desirable because a larger concentration would lead to more traps and result in a higher threshold voltage shift.

After forming the control dielectric 20, a control gate 22 is formed over the control dielectric 20. The control gate 22 may be polycrystalline silicon, a metal, metal alloy, the like, or combinations of the above. Any known method for depositing a conductive material can be used such as CVD, PVD, combinations thereof, and the like. The control gate 22 may be formed by any suitable method, such as CVD. If the control gate 22 is polysilicon it may be doped in-situ with a p-type dopant (or an n-type dopant depending of the type of semiconductor device formed) or, if desired, during subsequent processing using ion implantation. In addition, subsequent processing can optionally include salicidation of the polysilicon. Furthermore, if the control gate is polycrystalline silicon, the control gate 22 may be at least 100 nanometers in thickness

After depositing the control gate 22, the control gate 22, the control dielectric 20, the discrete charge storage elements 16, passivation 18, if present, and the tunnel dielectric 14 are patterned, as shown in FIG. 2. In one embodiment, this film stack is etched using a conventional silicon reactive ion etch (RIE) process. As a result of this patterning, a gate stack is formed. Next, source/drain regions 26 and 28 and spacer 24 are formed using conventional processing to produce the non-volatile memory device 10 illustrated in FIG. 2. Although not illustrated, the substrate can subsequently be processed using conventional methods to form interlevel dielectric (ILD) layers, interconnects, and additional device circuitry that can be used in conjunction with the non-volatile memory device.

By now it should be appreciated that there has been provided a method of in-situ incorporation of nitrogen in a silicon dioxide layer that can be used as a control dielectric in a non-volatile memory device. However, the silicon dioxide layer can be used in other devices, such as volatile memory devices (e.g., dynamic random access memories (DRAMs)). Furthermore, the silicon dioxide layer can be one of the dielectrics in a stacked gate dielectric structure that may be used for an input-output transistor or a high voltage transistor used for charging and discharging of memory transistors. When forming a non-volatile memory device using the above processes, the non-volatile memory device has good cross-wafer uniformity. In addition, the above process allows for the ability to control the nitrogen concentration and reduce the number of dangling bonds. Thus, charge trapping is decreased.

Although the invention is described herein with reference to specific embodiments, various modifications and changes can be made without departing from the scope of the present invention as set forth in the claims below. For example, discrete charge storage elements may not be formed in the non-volatile memory device. Instead, a continuous charge trapping layer (e.g., a nitride layer) may be formed. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to distinguish arbitrarily between the elements such terms describe. Thus, these terms are not necessarily intended to indicate temporal or other prioritization of such elements.

What is claimed is:

1. A method of forming a semiconductor device, the method comprising:
depositing a silicon dioxide layer over a substrate, wherein the depositing the silicon dioxide layer includes depositing the silicon dioxide layer to have a silicon concentration of greater than 30 atomic percent and a nitrogen concentration of less than 5 atomic percent, the depositing including:
flowing nitric oxide gas with a silicon precursor over the substrate with the substrate being at a temperature in a range of approximately 600 to approximately 900 degrees Celsius.

2. The method of claim 1 wherein the silicon precursor includes silane (SiH₄).

3. The method of claim 1 wherein the silicon precursor includes at least one of the group consisting of silicon tetrafluoride (SiF₄), difluorosilane (SiH₂F₂), fluorosilane (SiH₃F), and deuterated silane (SiD₄).

4. The method of claim 1 wherein the depositing includes flowing nitrous oxide gas with the nitric oxide gas and the silicon precursor over the substrate.

5. The method of claim 1 wherein the flowing includes flowing at least 5 times as much nitric oxide gas by volume as the silicon precursor.

6. The method of claim 1 further comprising:
forming a layer including charge storage memory material over the substrate;
wherein the depositing the silicon dioxide layer includes depositing the silicon dioxide layer on the layer including charge storage memory material.

7. The method of claim 6 wherein:
the forming the layer including charge storage memory material includes forming a layer of discrete charge storage elements over the substrate.

8. The method of claim 7 wherein:
the forming the layer including charge storage memory material includes passivating the discrete charge storage elements prior to the depositing.

9. The method of claim 1 further comprising:
forming a dielectric layer over the substrate;
wherein the depositing includes depositing the silicon dioxide layer on the dielectric layer.

10. The method of claim 1 wherein the depositing is characterized as a chemical vapor deposition process.

11. A method of forming a semiconductor device, the method comprising:
forming a layer including charge storage memory material over a substrate;
depositing a silicon dioxide layer over the layer including charge storage memory material, wherein the depositing the silicon dioxide layer includes depositing the silicon dioxide layer to have a silicon concentration of greater than 30 atomic percent and a nitrogen concentration of less than 5 atomic percent, the depositing including:
flowing nitric oxide gas with a silicon precursor over the layer.

12. The method of claim 11 wherein the depositing includes flowing nitric oxide gas with a silicon precursor over the layer with the layer being at a temperature in a range of approximately 600 to approximately 900 degrees Celsius.

13. The method of claim 11 wherein the forming the layer including charge storage memory material includes forming a layer of discrete charge storage elements over the substrate.

14. The method of claim 13 wherein the forming the layer including charge storage memory material includes passivating the discrete charge storage elements prior to the depositing.

15. The method of claim 13 wherein the discrete charge storage elements are characterized as silicon nanoclusters.

16. The method of claim 11 wherein the silicon precursor includes silane (SiH₄).

17. The method of claim 11 wherein the silicon precursor includes at least one of the group consisting of silicon tetrafluoride (SiF₄), difluorosilane (SiH₂F₂), fluorosilane (SiH₃F),and deuterated silane (SiD₄).

18. The method of claim 11 wherein the depositing includes flowing nitrous oxide gas with the nitric oxide gas and the silicon precursor over the layer.

19. A method of forming a semiconductor device, the method comprising:
forming a tunnel dielectric on semiconductor material;
forming a layer including charge storage memory material on the tunnel dielectric;
depositing a silicon dioxide layer on the layer including charge storage memory material, wherein the depositing the silicon dioxide layer includes depositing the silicon dioxide layer to have a silicon concentration of greater than 30 atomic percent and a nitrogen concentration of less than 5 atomic percent, the depositing including:
flowing nitric oxide gas with a silicon precursor over the layer with the layer being at a temperature in a range of approximately 600 to approximately 900 Celsius; and
forming a layer of gate material over the silicon dioxide layer.

20. The method of claim 19 further comprising:
patterning the layer of gate material, the silicon dioxide layer, and the layer including charge storage memory material, and the tunnel dielectric to form a gate stack for a non-volatile memory.
